(19) United States
(12) Patent Application Publication
(10) Pub. No.: US 2025/0008697 A1
(43) Pub. Date: Jan. 2, 2025

(54) DIE CONTACT TORSIONAL SPRINGS

(71) Applicant: Intel Corporation, Santa Clara, CA (US)

(72) Inventors: Juha Tapani Paavola, Hillsboro, OR (US); Shawn S. McEuen, Portland, OR (US); Kari Mansukoski, Hillsboro, OR (US); Sami Markus Heinisuo, Dallas, OR (US); Cody Hougnon, Hillsboro, OR (US)

(21) Appl. No.: 18/343,970

(22) Filed: Jun. 29, 2023

(51) Int. Cl. H05K 7/20

(52) U.S. Cl. CPC H05K 7/2049

(57) ABSTRACT

Die contact torsional springs are disclosed. A disclosed lid assembly for use with a circuit board includes a lid; a lug, a crank rotatably coupled to the lug, the crank including a spine, a jog to apply force to the lid, and a lever arm extending from the spine to apply a rotational moment to the spine when pressed against a surface.

### FIELD OF THE DISCLOSURE

This disclosure relates generally to die package supporting structures and, more particularly, to die contact torsional springs.

### BACKGROUND

Semiconductor device packages, such as die packages, are used in relatively thin and light computing devices, such as laptops, with relatively thin and compact motherboards. Typical cooling device attachments or supports, such as braces mounted to a motherboard, utilize board connection screws or other hardware.

### BRIEF DESCRIPTION OF THE DRAWINGS

FIG. 1 is an example lid assembly constructed in accordance with teachings of this disclosure.

FIG. 2 is a cutaway cross-sectional view of the example lid assembly of FIG. 1.

FIG. 3 is a detailed view of the example lid assembly shown in FIGS. 1 and 2.

FIG. 4 is an example alternative lid assembly constructed in accordance with teachings of this disclosure.

FIGS. 5A-5D depict alternative example crank geometries that can be implemented in examples disclosed herein.

FIG. 6 is a flowchart representative of an example method to produce and/or utilize examples disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Die contact torsional springs are disclosed. In typical computing devices, such as a laptop or other mobile computing device, a processor/die package is mounted to a printed circuit board (PCB) (e.g., a motherboard). Typically, the processor/die package is provided with a thermal gasket (e.g., a heat gasket) on a side that is opposite to that of the PCB. In turn, the thermal gasket is usually compressed by a lid or cover against the processor die/package to provide a heat conductive path for cooling thereof. Typically, the force to compress the thermal gasket is provided by a structural component or brace that is screwed onto the PCB such that the brace provides a clamping or compressive force onto the lid/cover. However, the implementation of the brace can reduce available spacing on the PCB for routing or traces, and also occupy a significant space or volume of a computing device. Further, the force applied by the brace to compress the thermal gasket can be applied to the processor/die package in a relatively uneven manner. Accordingly, the heat conductive path of the gasket me be compromised and inadequate cooling of the processor/die package may result.

Examples disclosed herein enable increased area for routing traces on PCBs. Further, examples disclosed herein enable computing device designs with increased compactness. Some examples disclosed herein enable greater distribution of compression and/or loading of die/processor packages and, as a result, greater cooling efficiency. Some examples disclosed herein can be cost-effectively manufactured/installed with relative ease, thereby reducing manufacturing time and associated labor.

In some examples disclosed herein, a lid (e.g., a plate, a cover, a cooling plate, a cold plate, etc.) is assembled to a fence that is coupled (e.g., soldered, integrated, assembled) to a PCB. In particular, the lid includes a lug that is coupled thereto and/or defined by features (e.g., stamped features, bent features, assembled features, etc.) of the lid. According to some examples disclosed herein, the lug is implemented to rotationally couple a crank to the cover such that the crank can rotate relative to the lid. In some examples disclosed herein, the crank includes a spine with a jog thereon. In some examples disclosed herein, the first spine is constrained by and rotatable about the lug (e.g., an opening of the lug). In some examples disclosed herein, the crank can be rotated to at least one rotational orientation and/or angular range in which the jog pushes on the plate to compress the plate against a semiconductor package (e.g., a die package) of the PCB and/or a gasket between the semiconductor package and the lid.

Further, a contact portion (e.g., a distal contact portion, a snap, a retainer, etc.) is formed on a lever arm, which extends from the spine and is angled from the spine. The contact portion is caused to engage a surface such that the contact portion is constrained in at least one rotational orientation, thereby inducing a rotational moment to cause the jog to push onto the lid. The surface can be associated with the PCB or the fence. According to examples disclosed herein, compression and/or twisting of the contact portion results in twisting of the first and second spines and, in turn, causes the jog of the spine to push onto the lid while the contact portion is retained and/or constrained.

Some examples include multiple splines, and/or one or more of the spine(s) include portions, sections and/or segments. In some examples, the contact portion is constrained and/or releasably couplable from a detent (e.g., a detent feature, a detent component, etc.) or an indent of the fence, a chassis/frame associated with the PCB and/or the PCB. In some examples, the contact portion contacts and is grounded to a plated surface and/or contact pad of the PCB. In some examples, the lug is positioned near a lateral edge of the lid. In some examples, the aforementioned fence surrounds a semiconductor package. Additionally or alternatively, the fence may include an aperture to constrain and/or receive a portion of the contact portion.

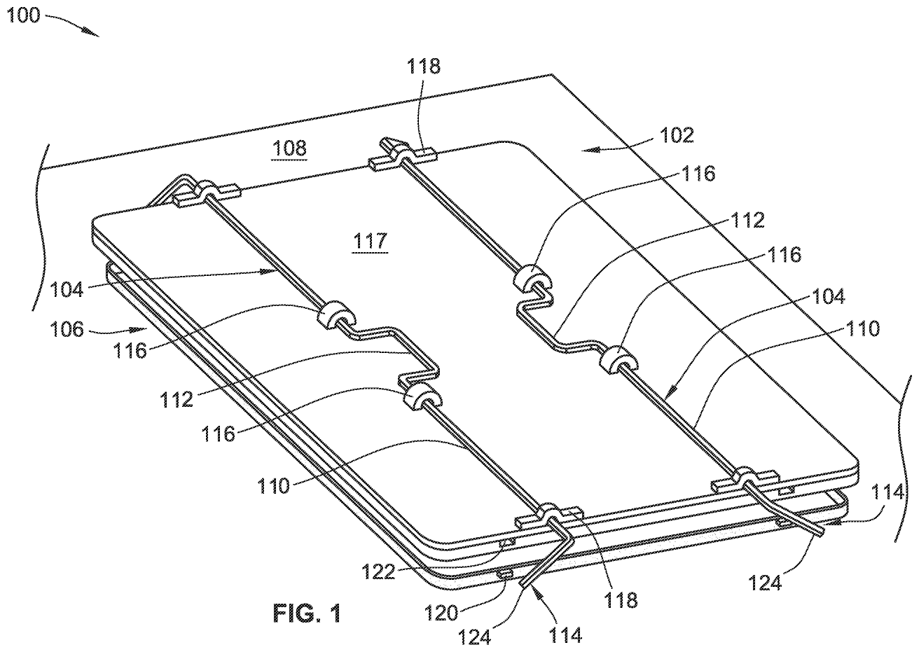

FIG. 1 is an example lid assembly 100 constructed in accordance with teachings of this disclosure. The lid assembly 100 of the illustrated example includes a lid (e.g., a cover, a plate, a cap, a shield, a means for covering, etc.) 102, and two cranks (e.g., torsional springs, rotatable cranks, rods, bent rods, etc.) 104. Although two of the cranks 104 are shown, other examples may include any other number of cranks (e.g., one, two, three, four, etc.). In the illustrated example of FIG. 1, the lid 102 is assembled to, placed on and/or coupled to a fence (e.g., a chassis, a fence chassis, means for supporting the means for covering, etc.) 106 that is soldered to a PCB 108. In this example, the fence 106 is an enclosure to at least partially surround electronic components and/or packages mounted to the PCB 108. In some examples, the fence 106 is formed on, part of and/or at least partially defines a chassis or other support structure (e.g., a computing device support structure, a frame, a chassis, etc.).

Each of the cranks 104 of the illustrated example includes a spine (e.g., a rod, a shaft, means for transmitting a rotational force, etc.) 110 with a jog (e.g., a lateral extension, a lateral bend, means for contacting the means for covering, etc.) 112 and a lever arm (e.g., a contact portion, a spine, a lever, a second spine, means for restraining, etc.) 114 angled from the spine 110. In particular, the lever arm 114 extends from a distal end of the spine 110 (e.g., two of the lever arms 114 extend from opposing distal ends of the spine 110). The lever arms 114 may also be referred to as legs, handles or levers. In some examples disclosed herein, the cranks 104 are positioned, restrained and/or aligned by lugs 116 on an outer surface 117 of the lid 102, as well as lugs 118 positioned near edges of the lid 102. Further, the example fence 106 includes contact portions (e.g., distal contact portions, a snap, a protrusion, etc.) 120 to be received by detents (e.g., snap locks, snap catches, etc.) 122. In other words, the fence 106 cooperates with the lid 102.

To provide a relatively uniform pressure between the lid 102 and the fence 106, cooling device/component and/or an electrical device and/or package at least partially surrounded by the fence 106, the jogs 112 of the cranks 104 are rotated to contact and engage the aforementioned outer surface 117 in at least one angular orientation. In particular, the spines 110 are rotated and translationally restrained in place by the lugs 116, 118 such that the jogs 112 push downward (in the view of FIG. 1) onto the outer surface 117, thereby causing the lid 102 to be applied with a force against the fence 106 such that, for example, a compressible thermal/heat gasket is compressed against a component, device and/or package mounted to the PCB 108.

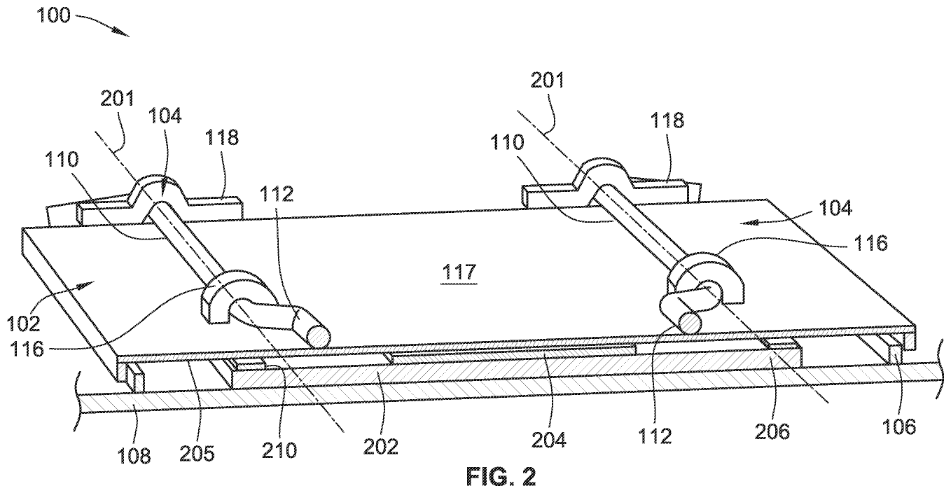

In this example, to maintain the spines 110 of the respective cranks 104 at an angular orientation as the jogs 112 apply force and pressure to the lid 102, two of the lever arms 114 on opposing sides (e.g., opposing longitudinal sides or ends, etc.) of the spine 110 are pressed against a surface of the PCB 108. In particular, contact of the distal ends 124 of the lever arms 114 with the PCB 108 causes the lever arms 114 to be elastically deformed and/or flexed in view of the constraints provided by the lugs 118 (and the lugs 116) positioning the spines 110 at a predefined distance (e.g., a vertical distance in the view of FIG. 1) from the PCB 108. In particular, the jogs 112 are caused to be urged against the top surface 117 as the lever arms 114 rotate and/or rotationally twist in flexure. In other words, the spines 110 and the lever arms 114 cause the crank 104 to act as a torsional spring with a rotational moment/force that pushes down on and/or applies pressure/force to the lid 102 via the jogs 112. In this example, pressing the lid 102 onto the fence 106 such that the contact portions 120 engage the respective detents 122 causes the lever arms 114 to be pushed against the surface of the PCB 108, thereby inducing a rotational moment of the spine 110 that causes the jogs 112 to push downward on the lid 102 (in the view of FIG. 2). According to some examples disclosed herein, an angular difference between the jog 112 and the lever arm(s) 114 causes a torsional load of the crank 104 to drive the jog 112 against the lid 102. However, any other appropriate locking or force application methodology can be implemented instead.

In some examples, the lugs 116, 118 are soldered and/or welded to the lid 102. In other words, the lugs 116, 118 may be rigidly coupled to the lid 102. Additionally or alternatively, the lugs 116, 118 may be formed as features of the lid 102 (e.g., bent portions of sheet metal, a cast feature, etc.). According to some examples disclosed herein, the lugs 116, 118 are formed as stamped features of the lid 102.

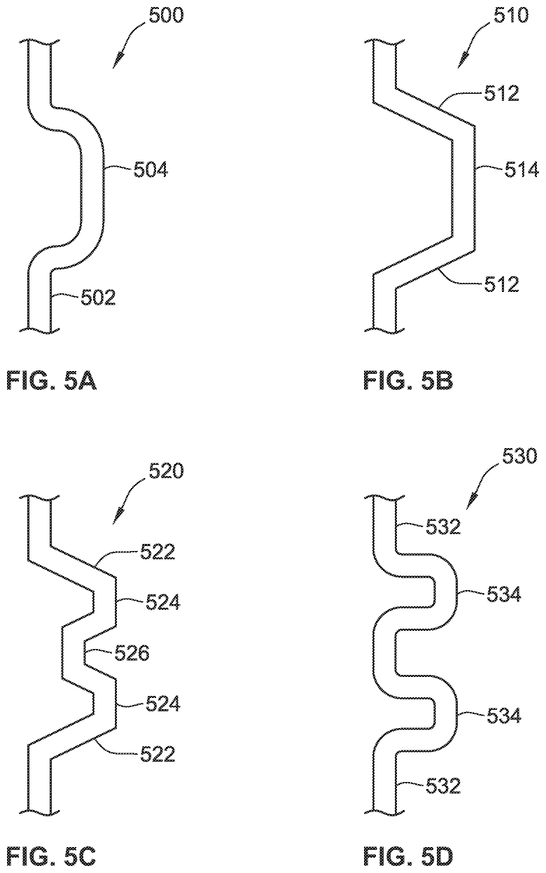

While the jogs 112 are shown as having a generally rectangular shape (e.g., a generally rectangular bend shape), the jogs 112 can be any appropriate shape including, but not limited to, curved shapes, spline shapes, ellipsoid shapes, etc., as discussed below in connection with FIGS. 5A-5D. Further, while two of the cranks 104 are shown implemented in the example of FIG. 1, any other appropriate number of the cranks 104 can be implemented instead (e.g., one, three, four, five, ten, twenty, etc.). Further, the lid 102 can be utilized in examples to cover a plurality of electronic components and/or circuitry (e.g., dies and/or die packages), for example.

FIG. 2 is a cutaway cross-sectional view of the example lid assembly 100 of FIG. 1. In the illustrated example of FIG. 2, the cranks 104 are shown rotationally coupled to the lid 102. In particular, the example cranks 104 are held in place against the surface 117 by the lugs 116, 118 described above in connection with FIG. 1. However, while the example lugs 116, 118 constrain the spines 110 from translating (horizontally and vertically in the view of FIG. 2), the lugs 116, 118 enable the spines 110 of the cranks 104 to rotate and/or pivot about respective axis of rotations 201.

To provide a thermally conductive path between a die (e.g., a die package, a die component, a board-mounted die, etc.) 202 that is mounted to the aforementioned PCB 108, a thermal gasket (e.g., a heat gasket, means for heat conduction, etc.) 204 is compressed at a side 205 of the lid 102 that is opposite to the side 117 of the lid 102. In particular, the rotational displacement of the spines 110 causes the respective jogs 112 to be pressed against the first surface 117 of the lid 102 and, in turn, a surface corresponding to the side 205 of the lid 102 pushes against the thermal gasket 204, thereby enabling an effective thermal/heat conductive path between the lid 102 and the die 202. Examples disclosed herein can advantageously provide a relatively even compression load across the thermal gasket 204 for increased thermal conductivity. Further, the arrangement and/or relative positioning of the cranks 104 enables a cooling device, such as a heat pipe a vapor chamber, to be coupled and/or attached to an area of the side 117 proximate the die 202 to advantageously cool the die 202. In other words, examples disclosed herein enable advantageous placement of the cooling device while enabling a relatively even pressure to be applied across the lid 102 and/or the die 202, thereby increasing heat dissipation via the lid 102. In some examples, a spacer 210 is implemented to control gaps and/or overall assembly thickness(es).

According to examples disclosed herein, the cranks 104 and/or the lid 102 can be at least partially composed of a metal, such as, but not limited to, steel, stainless steel, aluminum, copper, nickel silver, etc. In some examples, the cranks 104 are approximately 0.7 millimeters (mm) to 1.2 mm (e.g., 1.0 mm) in diameter. While the spines 110 and the lever arms 114 are depicted as having a generally circular and/or ellipsoid shape cross-sectional profile, in some examples, the spines 110 and the lever arms 114 can implement any other appropriate cross-sectional profile shape including, but not limited to, rectangular, square, hexagonal, octagonal, etc.

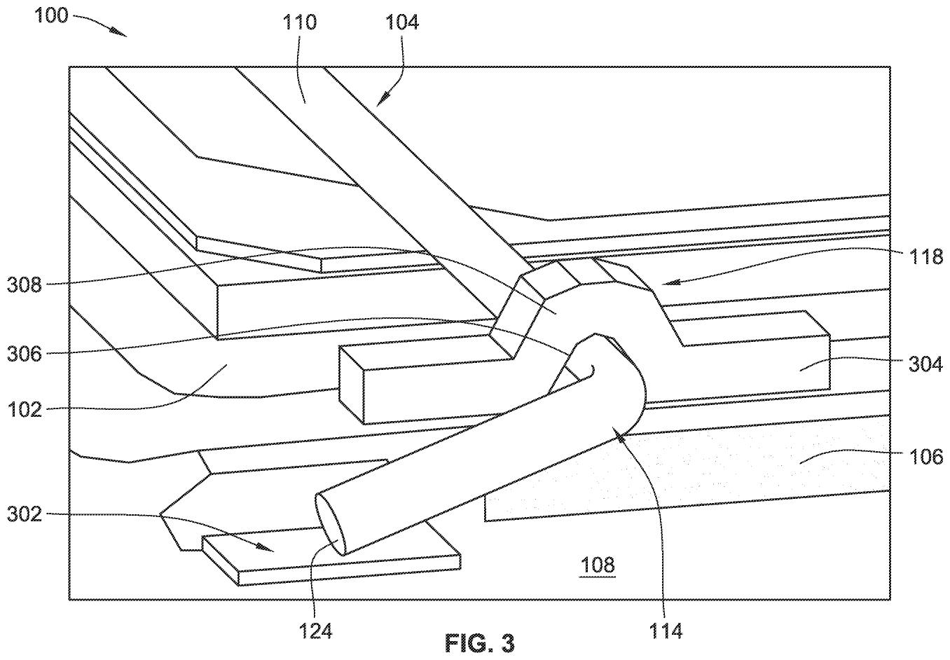

FIG. 3 is detailed view of the example lid assembly 100 shown in FIGS. 2 and 3. In the illustrated example of FIG. 3, a detailed view of the lever arm 114 being at least partially constrained by the lug 118 is shown. In this example, the lever arm 114 contacts a pad (e.g., a contact pad, a copper ground pad, a conductive pad, etc.) 302, which can be part of and/or integral with the PCB 108 or the fence 106. The example lever arm 114 contacts the pad 302 at the distal end 124 thereof. In particular, the example lug 118 applies a downward force (in the view of FIG. 3) on the spine 110 such that the distal end 124 of the lever arm 114 presses against the pad 302, which is at least partially composed of metal and functions as a grounding pad for the crank 104 and/or the lid 102 (e.g., for electromagnetic (EMI) mitigation purposes).

To apply the downward force on the distal end 124 of the lever arm 114, the lug 118 includes a base 304 and an inner contact surface 306 defined by an arch 308 such that the inner contact surface 306 provides a downward reaction force (in the view of FIG. 3) on the spine 110 and, in turn, presses the lever arm 114 against the pad 302. This downward reaction force results from the lid 102 being coupled to (e.g., snapped to) the fence 106. In other examples, a detent or other feature is utilized to restrain the lever arm 114 and/or cause a twisting/torsional force on the spine 110 to enable the jog 112 shown in FIGS. 1 and 2 to press against the lid 102 with a force for compression of the thermal gasket 204 shown in FIG. 2.

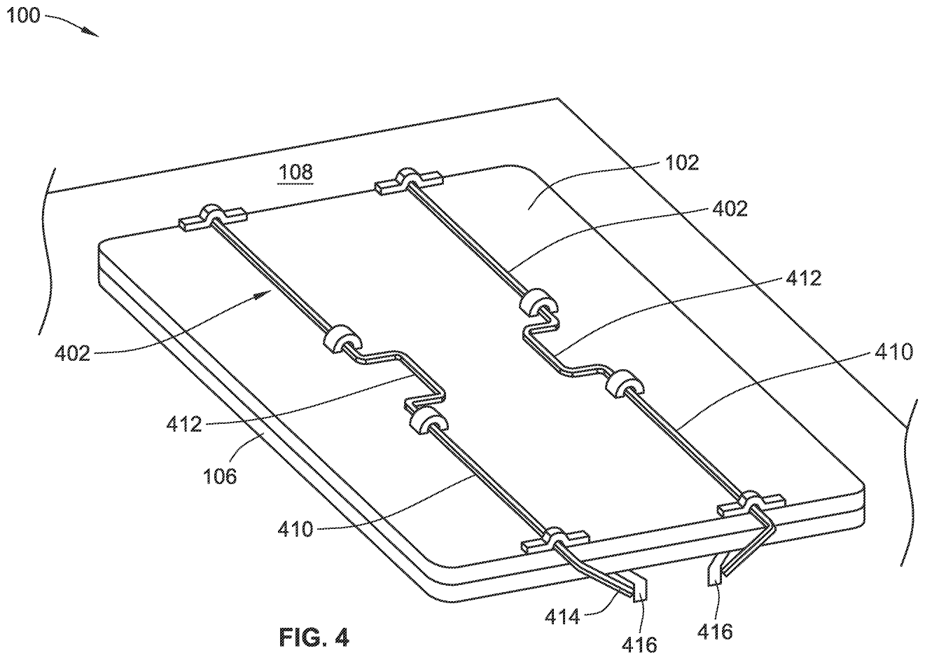

FIG. 4 is an example alternative lid assembly 400 in accordance with teachings of this disclosure. The example lid assembly 400 is similar to the lid assembly 100 shown in FIGS. 1-3, but instead includes an inverted crank arrangement. The lid assembly 400 of the illustrated example includes the lid 102 having cranks 402 rotationally coupled thereto. Similar to the example lid assembly 100, the lid 102 is removably couplable to the fence 106, which is mounted to the PCB 108. In turn, each of the example cranks 402 includes a first spine 410 with a jog 412 defined thereon, as well as a lever arm 414 that is angled from the spine 410. In contrast to the example lid assembly 100, the lever arm 414 does not generally extend along a direction that opposes the jog 412.

To cause the jogs 412 to push against the lid 102, the lever arm 414 is rotated (along with the first spine 410) to an angular orientation and/or angular orientation range that induces a twisting moment of the spine 410 and, thus, the jog 412. In this example, the lever arm 414 is rotationally constrained by a detent 416 to press the jog 412 against the lid 102. In other words, the example lever arm 414 is received by or pressed against a surface of the detent 416. The example detent 416 can be defined by and/or integral with the fence 106, the PCB 108 and/or the lid 102. In a particular example, a protrusion and/or surface of the lid 102 defines the aforementioned detent 416. In other examples, an indent or aperture of the fence 106 or the PCB 108 retains and/or locks the lever arm 414 in an angular orientation that transmits a bending moment of the spine 410 and the jog 412.

FIGS. 5A-5D depict alternative example crank geometry that can be implemented in examples disclosed herein. Any of the example features and/or aspects of 5A-5D can be utilized in conjunction with or in lieu of any of the example disclosed herein.

Turning to FIG. 5A, an example jog 500 is shown with a spine 502 having a curved portion 504 resembling an arc. Additionally or alternatively, the curved portion 504 can resemble a half circle, a circular portion, an ellipsoid, etc.

FIG. 5B depicts an example jog 510 including a converging portion 512 as well as a straight portion 514. In this example, the converging portion 512 and the straight portion 514 define a generally converging shape of the jog 510. In other examples, a diverging shape is utilized in contrast to the converging shape shown with respect to the jog 510.

Turning to FIG. 5C, an example jog 520 is depicted including converging ends 522 with contact portions 524, as well as an indented portion (e.g., a central indented portion) 526. In other examples, multiple ones of the indented portion 526 are utilized across the jog 520.

In the illustrated example of FIG. 5D, a jog 530 includes a spine 532 with multiple rectangular portions 534 arranged thereon. In this example, the rectangular portions 534 represent a pulse shape (e.g., a rectangular pulse shape). While two of the rectangular portions 534 are implemented in this example. Any other appropriate number of the rectangular portions 534 can be implemented instead (e.g., three, four, five, ten, twenty, thirty, etc.).

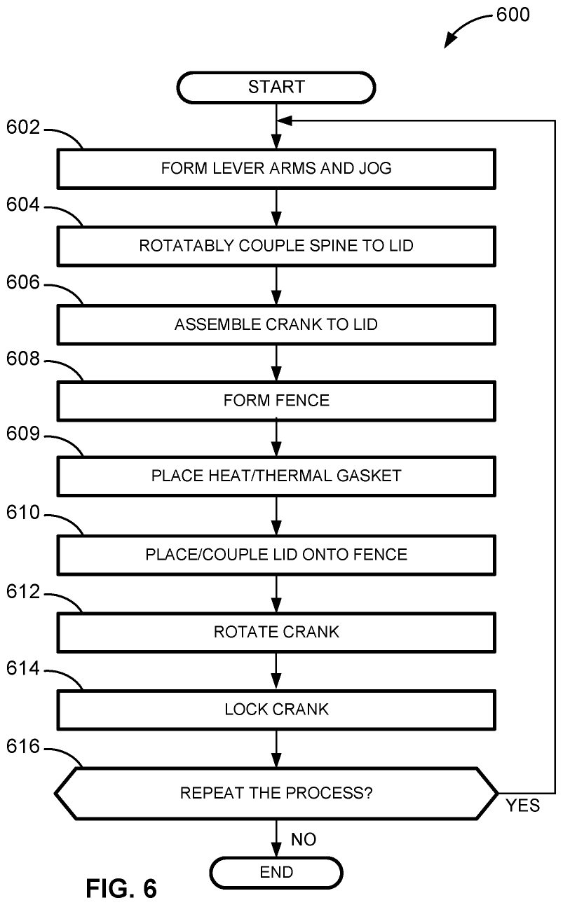

FIG. 6 is a flowchart representative of an example method 600 to produce examples disclosed herein. The example method 600 can be performed to produce, manufacture, assemble and/or retrofit examples disclosed herein onto a computing device and/or PCB, for example. In other words, the example method 600 can be implemented during manufacturing, assembly or an update/retrofit, for example.

At block 602, levers (e.g., lever arms) as well as jogs are formed on a spine to define a crank (e.g., the crank 104, the crank 402). According to examples disclosed herein, the jogs and the levers are integral with the spine (e.g., the jogs and the levers are defined by bending the spine). In this example two of the levers are formed on opposing distal ends of the spine.

At block 604, the spine of the crank is rotationally coupled to a lid (e.g., the lid 102). In the illustrated example of FIG. 6, the spine is rotationally coupled to the plate via a lug (e.g., the lug 116, the lug 118) such that the spine is prevented from translating in at least two different directions while enabling rotation of the spine about its longitudinal axis.

At block 606, additionally or alternatively, the example crank is assembled and/or coupled to the lid. For example, the crank can be further constrained to the lid subsequent to the spine being rotationally coupled to the lid. In such examples, additional features (e.g., additional bends of the lid, a mounted component, etc.) are coupled to the lid to further constrain the crank.

At block 608, in some examples, a fence is formed. The fence may be defined on a PCB or assembled thereto. In some such examples, the fence is fabricated (e.g., a metal fabrication process) prior to being assembled to the PCB.

At block 609, in some examples, a thermal gasket (e.g., a compressible thermal gasket, a heat gasket) is placed between the lid and a heat generating component (e.g., an electronic device, a die package, a board mounted device, etc.) of a PCB (e.g., the PCB 108). According to some examples disclosed herein, the thermal gasket is compressed between the lid and the heat generating component.

In this example, at block 610, the lid is placed onto and/or coupled to the fence. For example, the lid is pressed onto the fence and retained to the fence with a snap interface therebetween. In other examples, a feature (e.g., an indent, a detent, a locking arm, etc.) of the PCB and/or a feature of a structure supported by the PCB is utilized to hold and/or compress the lid against the fence. In some examples, the thermal gasket or paste is assembled and/or applied between the plate and a die package of the PCB.

At block 612, the crank is rotated about a rotational axis defined by the lug. In some examples, the crank is rotated by placing the lid onto the fence (e.g., in a torsional spring configuration of the crank). In particular, coupling (e.g., snapping) the lid to the fence causes a compressible force applied against at least a portion of the crank that induces a twisting moment and/or force in the crank. In some examples, the crank is rotated until a distal end, a lever arm and/or snap of the crank engages a detent or an indent, for example. In some examples disclosed herein, rotating the crank causes compression of the aforementioned thermal gasket positioned between the lid and the heat generating component of the PCB.

At block 614, in some examples, the crank is rotationally locked and/or constrained. In this example, the crank is rotationally locked and/or constrained based on a lever arm thereof being pressed against a surface, indent and/or detent of the PCB when the lid is coupled to the fence. In other words, assembling the lid with the crank to the fence causes the crank to be torsionally loaded, thereby pressing the jog of the crank onto the lid. In some other examples, a user rotates the crank until the lever is retained by a surface, indent and/or detent.

At block 616, it is determined whether to repeat the process. If the process is to be repeated (block 610), control of the process returns to block 602. Otherwise, the process ends. This determination may be based on whether additional lid assemblies are to be produced and/or whether additional cranks are to be assembled to the plate.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

As used herein, the terms “lever” and “lever arm” refer to an object, an extension, a protrusion, a bend and/or a component extending from a spine at a perpendicular angle or any other appropriate angle. As used herein, the term “jog” refers to an object, an extension, a protrusion, a bend and/or a component that extends laterally from a spine.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

Example methods, apparatus, systems, and articles of manufacture that can distribute force on an electronics component in a relatively manner are disclosed herein. Further examples and combinations thereof include the following:
Example 1 includes a lid assembly comprising a lid, a lug, and a crank rotatably coupled to the lug, the crank including a spine, a jog to apply force to the lid, and a lever arm extending from the spine to apply a rotational moment to the spine when pressed against a surface.
Example 2 includes the lid assembly as defined in example 1, further including a heat gasket.
Example 3 includes the lid assembly as defined in example 2, wherein the jog is to further cause the lid to compress the heat gasket against a die package.
Example 4 includes the lid assembly as defined in any of examples 1 to 3, further including a fence to cooperate with the lid.
Example 5 includes the lid assembly as defined in example 4, wherein the fence includes at least one of a an indent or a detent to constrain the lever arm.
Example 6 includes the lid assembly as defined in example 5, wherein the detent includes an aperture to receive at least a portion of the lever arm.
Example 7 includes the lid assembly as defined in any of examples 1 to 6, wherein the lug is a first lug, and further including a second lug at an edge of the lid to further constrain the spine of the crank.
Example 8 includes the lid assembly as defined in any of examples 1 to 7, wherein the lever arm extends from a distal and of the spine.
Example 9 includes the lid assembly as defined in any of examples 1 to 8, wherein the lug is soldered to the lid.
Example 10 includes the lid assembly as defined in any of examples 1 to 9, wherein the lug includes a stamped feature of the lid.
Example 11 includes an electronic device comprising electronic circuitry, a lid, a torsional spring including a spine with a jog, the jog to apply force to the lid when rotational force is applied to the spine, and a lever arm at an end of the torsional spring, the lever arm to transmit the rotational force to the spine when the lever arm is pressed against a surface.
Example 12 includes the electronic device as defined in example 11, wherein the lever arm is releasably locked to at least one of a detent or an indent.
Example 13 includes the electronic device as defined in example 12, wherein at least a portion of the lever arm is to be received by an aperture of the chassis.
Example 14 includes the electronic device as defined in any of examples 11 to 13, further including a lug on the lid to rotationally couple the torsional spring.
Example 15 includes the electronic device as defined in example 14, wherein the lug is a first lug positioned away from an edge of the lid, and further including a second lug at or proximate the edge of the lid.
Example 16 includes the electronic device as defined in any of examples 11 to 15, further including a heat gasket positioned between the lid and a die package.
Example 17 includes the electronic device as defined in any of examples 11 to 16, wherein the lever arm is a first lever arm on a first end of the spine, and further including a second lever arm at a second end of the spine opposite the first end.
Example 18 includes a method comprising forming lever arms at opposite ends of a spine, and a jog between the lever arms, and rotatably coupling the spine to a lid such that the lever arms extend beyond the lid.
Example 19 includes the method as defined in example 18, further including forming a fence to cooperate with the lid.
Example 20 includes the method as defined in any of examples 18 or 19, further including placing the lever arms to extend below to the fence.
Example 21 includes an apparatus comprising means for covering, means for transmitting a rotational force, means for contacting the means for covering, and means for restraining.
Example 22 includes the apparatus as defined in example 21, further including means for heat conduction.
Example 23 includes the apparatus as defined in any of examples 21 or 22, further including means for supporting the means for covering.

From the foregoing, it will be appreciated that example systems, apparatus, articles of manufacture, and methods have been disclosed that enable relatively uniform compression of a lid and/or a cover onto electronic component(s) and/or other structure(s). Examples disclosed herein can also enable increased trace routing space/area for PCBs. Examples disclosed herein are cost-effective and relatively easy to manufacture, implement and/or integrate. Examples disclosed herein can improve thermal efficiency and/or heat transfer by providing more effective compression of thermal interface materials relative to heat generating components and enabling more direct contact to cooling devices, such as heat pipes or vapor chambers, for example.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A lid assembly comprising:
a lid;
a lug; and
a crank rotatably coupled to the lug, the crank including:
a spine,
a jog to apply force to the lid, and
a lever arm extending from the spine to apply a rotational moment to the spine when pressed against a surface.

2. The lid assembly as defined in claim 1, further including a heat gasket.

3. The lid assembly as defined in claim 2, wherein the jog is to further cause the lid to compress the heat gasket against a die package.

4. The lid assembly as defined in claim 1, further including a fence to cooperate with the lid.

5. The lid assembly as defined in claim 4, wherein the fence includes at least one of an indent or a detent to constrain the lever arm.

6. The lid assembly as defined in claim 5, wherein the indent or the detent includes an aperture to receive at least a portion of the lever arm.

7. The lid assembly as defined in claim 1, wherein the lug is a first lug; and further including a second lug at an edge of the lid to further constrain the spine of the crank.

8. The lid assembly as defined in claim 1, wherein the lever arm extends from a distal and of the spine.

9. The lid assembly as defined in claim 1, wherein the lug is soldered to the lid.

10. The lid assembly as defined in claim 1, wherein the lug includes a stamped feature of the lid.

11. An electronic device comprising:
electronic circuitry;
a lid;
a torsional spring including a spine with a jog, the jog to apply force to the lid when rotational force is applied to the spine; and
a lever arm at an end of the torsional spring, the lever arm to transmit the rotational force to the spine when the lever arm is pressed against a surface.

12. The electronic device as defined in claim 11, wherein the lever arm is releasably locked to at least one of a detent or an indent.

13. The electronic device as defined in claim 12, wherein at least a portion of the lever arm is to be received by an aperture of the chassis.

14. The electronic device as defined in claim 11, further including a lug on the lid to rotationally couple the torsional spring.

15. The electronic device as defined in claim 14, wherein the lug is a first lug positioned away from an edge of the lid, and further including a second lug at or proximate the edge of the lid.

16. The electronic device as defined in claim 11, further including a heat gasket positioned between the lid and a die package.

17. The electronic device as defined in claim 11, wherein the lever arm is a first lever arm on a first end of the spine, and further including a second lever arm at a second end of the spine opposite the first end.

18. An apparatus comprising:
means for covering;
means for transmitting a rotational force;
means for contacting the means for covering; and
means for restraining.

19. The apparatus as defined in claim 18, further including means for heat conduction.

20. The apparatus as defined in claim 18, further including means for supporting the means for covering.
